(19) United States
(12) Patent Application Publication
(10) Pub. No.: US 2024/0204063 A1
(43) Pub. Date: Jun. 20, 2024

(54) SEMICONDUCTOR DEVICE WITH BACKSIDE U-SHAPED SILICIDE

(71) Applicant: International Business Machines Corporation, Armonk, NY (US)

(72) Inventors: Ruilong Xie, Niskayuna, NY (US); Kisik Choi, Watervliet, NY (US); Lawrence A. Clevenger, Saratoga Springs, NY (US); Oleg Gluschenkov, Tannersville, NY (US); Nicholas Anthony Lanzillo, Wynantskill, NY (US)

(21) Appl. No.: 18/067,748

(22) Filed: Dec. 19, 2022

(51) Int. Cl. H01L 29/417; H01L 21/8238; H01L 27/092; H01L 29/06; H01L 29/08; H01L 29/40; H01L 29/786

(52) U.S. Cl. CPC H01L 29/41733; H01L 21/823814; H01L 21/823871; H01L 27/092; H01L 29/0653; H01L 29/0847; H01L 29/401; H01L 29/78696; H01L 29/0673; H01L 29/66545

(57) ABSTRACT

A semiconductor device is provided. The semiconductor device includes a field effect transistor (FET) structure having a source/drain (S/D) region between channel regions, primary epitaxy disposed in the S/D region and a backside contact disposed in contact with and gouging into the primary epitaxy.

### BACKGROUND

The present invention generally relates to fabrication methods and resulting structures for semiconductor devices. More specifically, the present invention relates to a semiconductor device fabrication method to form a semiconductor device with backside U-shaped silicide.

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### SUMMARY

Embodiments of the invention are directed to a semiconductor device. A non-limiting example of the semiconductor device includes a field effect transistor (FET) structure having a source/drain (S/D) region between channel regions, primary epitaxy disposed in the S/D region and a backside contact disposed in contact with and gouging into the primary epitaxy.

Embodiments of the present invention are directed to a semiconductor device. A non-limiting example of the semiconductor device includes a backside power rail, a field effect transistor (FET) structure having source/drain (S/D) regions between channel regions, primary epitaxy disposed in each of the S/D regions and a backside contact disposed in contact with the backside power rail and the primary epitaxy in a first one of the S/D regions and gouging into the primary epitaxy in the first one of the S/D regions.

Embodiments of the present invention are directed to a semiconductor device fabrication method. A non-limiting example of the semiconductor device fabrication method includes forming bottom dielectric isolation (BDI) under a gate structure with a source/drain (S/D) region and replacing a portion of the BDI in the S/D region with a sacrificial placeholder. In addition, the semiconductor device fabrication method further includes growing primary epitaxy over the sacrificial placeholder, using the sacrificial placeholder to create an opening, removing the sacrificial placeholder, enlarging the opening, growing backside trench epitaxy in contact with the primary epitaxy and within the opening, forming sacrificial spacers in a periphery of a remaining portion of the opening to define an aperture, gouging into the backside trench epitaxy and the primary epitaxy via the aperture to form a contact opening and forming a backside contact by metallization of the contact opening.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a flow diagram illustrating a method of semiconductor device fabrication in accordance with one or more embodiments of the present invention;

FIG. 2 depicts a top-down view of a semiconductor device according to one or more embodiments of the present invention;

FIG. 3 is a side view of an initial structure of a semiconductor device in accordance with one or more embodiments of the present invention;

FIG. 4 is a side view of a first intermediate structure of a semiconductor device following formation of a sacrificial placeholder applied to the initial structure of FIG. 3 in accordance with one or more embodiments of the present invention;

FIG. 5 is a side view of a second intermediate structure of a semiconductor device following growth of source/drain (S/D) epitaxy, interlayer dielectric (ILD) deposition and chemical mechanical polishing (CMP), dummy gate replacement with high-k metal gate material, middle-of-line (MOL) and back-end-of-line (BEOL) formation and carrier wafer bonding applied to the first intermediate structure of FIG. 4 in accordance with one or more embodiments of the present invention;

FIG. 6 is a side view of a third intermediate structure of a semiconductor device following substrate removal, backside ILD deposition and CMP and sacrificial placeholder removal applied to the second intermediate structure of FIG. 5 in accordance with one or more embodiments of the present invention;

FIG. 7 is a side view of a fourth intermediate structure of a semiconductor device following enlargement of opening, growth of backside trench S/D epitaxy and sacrificial spacer deposition applied to the third intermediate structure of FIG. 6 in accordance with one or more embodiments of the present invention;

FIG. 8 is a side view of a fifth intermediate structure of a semiconductor device following epitaxial gouging and sacrificial spacer removal applied to the fourth intermediate structure of FIG. 7 in accordance with one or more embodiments of the present invention; and

FIG. 9 is a side view of a final structure of a semiconductor device following formation of a backside contact by metallization and formation of a backside power rail and a backside power distribution network (BSPDN) applied to the fifth intermediate structure of FIG. 8 in accordance with one or more embodiments of the present invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, a field effect transistor (FET) typically has a source, a channel and a drain where current flows from the source to the drain as well as a gate that controls the flow of current through the device channel. FETs can have a variety of different structures. For example, FETs have been fabricated with the source, channel and drain formed in a substrate material itself, where the current flows horizontally (i.e., in the plane of the substrate). As another example, FinFETs have been formed with the channel extending outwardly from the substrate, but where the current also flows horizontally from the source to the drain. The channel for the FinFET can be an upright slab of thin rectangular silicon (Si), commonly referred to as the fin with a gate on the fin, as compared to a metal-oxide-semiconductor FET (MOSFET) with a single gate parallel with the plane of the substrate. Depending on doping of the source and drain, an n-doped FET (nFET) or a p-doped FET (pFET) can be formed. Two FETs also can be coupled to form a complementary metal-oxide-semiconductor (CMOS) device, where a p-channel MOSFET and n-channel MOSFET are coupled together.

In certain logic circuits in which FETs are employed, contacts are provided to allow for electrical communication between source/drain (S/D) epitaxy of FET devices and external features. Frontside contacts allow for electrical communication between FET devices and middle-of-line (MOL) or back-end-of-line (BEOL) layers whereas backside contacts allow for electrical communication between S/D epitaxy of FET devices and backside power rails or backside power delivery networks (BSPDN). The total resistance of these connections, i.e., the connection of a metal backside contact to S/D epitaxy of an FET, is dominated by the metal-to-epitaxy contact resistivity. In fact, it has been observed that this “contact resistance” effectively forms a bottleneck for next generation logic circuits.

A need therefore remains for a semiconductor device exhibiting reduced contact resistance, such as metal-to-epitaxy contact resistivity, between a metal contact and S/D epitaxy of an FET device.

Turning now to an overview of the aspects of the invention, one or more embodiments of the invention address the above-described shortcomings of the prior art by providing a method of semiconductor device fabrication. The method includes forming bottom dielectric isolation (BDI) under a gate structure and forming a sacrificial placeholder under original S/D epitaxy of the gate structure followed by wafer flipping and substrate removal. The method further includes removing the sacrificial placeholder, enlarging a contact size, forming backside trench epitaxy in contact with the original S/D epitaxy, forming sacrificial spacers and contact gouging into the backside trench epitaxy and the original S/D epitaxy. In addition, the method includes removing the sacrificial spacers and forming a backside contact by metallization.

The above-described aspects of the invention address the shortcomings of the prior art by providing for a semiconductor device that includes a backside power rail and a backside contact by which the backside power rail is electrically connected to S/D epitaxy.

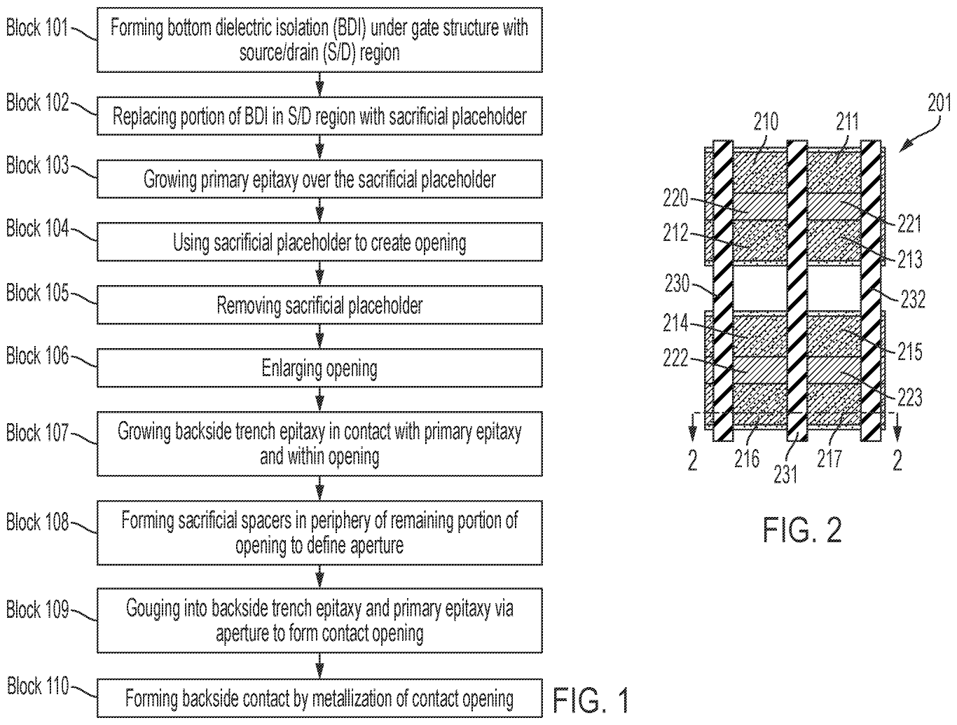

Turning now to a more detailed description of aspects of the present invention, FIG. 1 depicts a method of semiconductor device fabrication 100 according to one or more embodiments of the present invention.

As shown in FIG. 1, the method of semiconductor device fabrication 100 includes forming bottom dielectric isolation (BDI) under a gate structure with a source/drain (S/D) region (block 101) and replacing a portion of the BDI in the S/D region with a sacrificial placeholder (block 102). The method of semiconductor device fabrication 100 further includes growing primary epitaxy over the sacrificial placeholder (block 103), using the sacrificial placeholder to create an opening (block 104), removing the sacrificial placeholder (block 105) and enlarging the opening (block 106) by widening the opening. In addition, the method of semiconductor device fabrication 100 also includes growing backside trench epitaxy in contact with the primary epitaxy and within the opening (block 107), forming sacrificial spacers in a periphery of a remaining portion of the opening to define an aperture (block 108), gouging into the backside trench epitaxy and the primary epitaxy via the aperture to form a contact opening (block 109) and forming a backside contact by metallization of the contact opening (block 110). The contact opening can be formed with a diameter (i.e., a maximum diameter) that is smaller than that of the backside trench epitaxy and the primary epitaxy. The contact opening can have a V-shape or a U-shape, for example, although other shapes for the contact opening are possible.

With reference to FIGS. 2-8B, the method of semiconductor device fabrication 100 of FIG. 1 will now be described in greater detail.

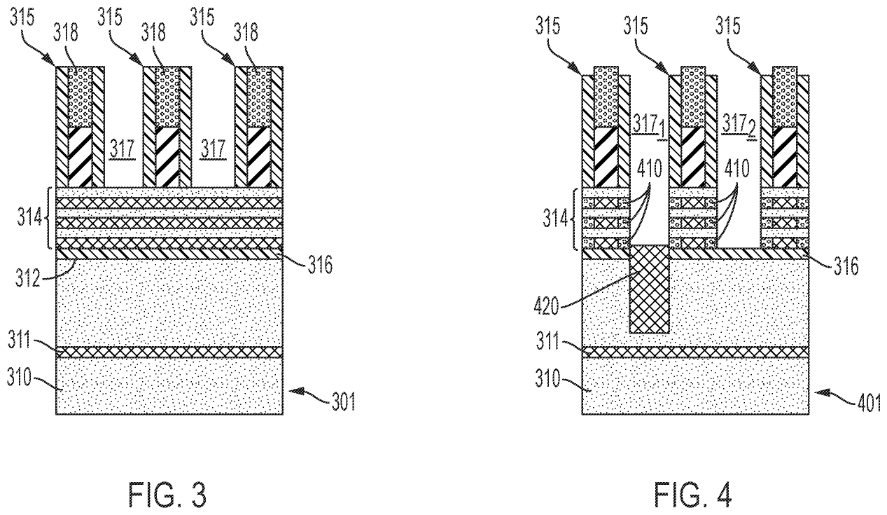

FIG. 2 depicts a top-down view of semiconductor device 201 being fabricated and illustrates that the semiconductor device 201 will eventually include active nFET regions 210, 211, active nFET regions 212, 213, active pFET regions 214, 215 and active pFET regions 216, 217 as well as non-active regions 220, 221 and non-active regions 222, 223 and gates 230, 231, 232. The gates 230, 231, 232 span the active nFET regions 210, 211, the active nFET regions 212, 213, the active pFET regions 214, 215 and the active pFET regions 216, 217 as well as the non-active regions 220, 221 and the non-active regions 222, 223. FIGS. 3-9 are cross-sectional views of varying stages of semiconductor device fabrication which correspond to line 2-2 of FIG. 2.

As shown in FIG. 3, an initial structure 301 of a semiconductor device is provided in accordance with one or more embodiments of the present invention. The initial structure 301 includes a semiconductor substrate 310, which is bisected by a semiconductor layer 311. In an exemplary case, the semiconductor substrate 310 can include silicon and the semiconductor layer 311 can include silicon germanium. The semiconductor substrate 310 has an uppermost surface 312. The initial structure 301 further includes nanosheet layers 314, which are made up of interleaved layers of differing semiconductor materials (i.e., silicon and silicon germanium), dummy gate structures 315 disposed on an uppermost layer of the nanosheet layers 314 and bottom dielectric isolation (BDI) 316. The BDI 316 is interposed between the uppermost surface 312 and a lowermost layer of the nanosheet layers 314 so that the BDI underlies the dummy gate structures 315.

Each dummy gate structure 315 is formed at a distance from a neighboring dummy gate structure 315 to define S/D regions 317 between channel regions 318.

As shown in FIG. 4, a first intermediate structure 401 of a semiconductor device is provided. The first intermediate structure 401 results from nanosheet recession, indentation of certain ones of the nanosheet layers 314 (i.e., the silicon germanium layers), formation of inner spacers 410 and subsequent formation of a sacrificial placeholder 420 applied to the initial structure 301 of FIG. 3. The nanosheet recession, the indentation of the certain ones of the nanosheet layers 314 (i.e., the silicon germanium layers) and the formation of the inner spacers 410 give each of the dummy gate structures 315 a gate-all-around (GAA) nanosheet (NS) FET configuration. It is to be understood, however, that this is not required and that other configurations are possible. For purposes of clarity and brevity, the following description will relate to the case of the dummy gate structures 315 as being configured as GAA NS FETs. The nanosheet recession exposes the BDI 316 in a first one 3171 of the S/D regions 317. This allows for the formation of the sacrificial placeholder 420 in the first one 3171 of the S/D regions 3171 by depositional processing for example.

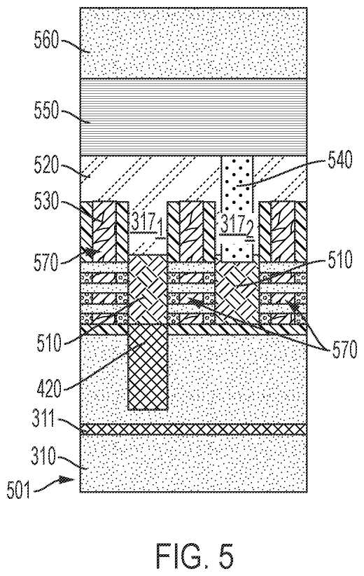

As shown in FIG. 5, a second intermediate structure 501 of a semiconductor device is provided following several processing operations applied to the first intermediate structure 401 of FIG. 4. The several processing operations can include, but are not limited to, growth of primary source/drain (S/D) epitaxy 510 in a second one 3172 of the S/D regions and over the sacrificial placeholder 420 in the first one 3171 of the S/D regions 317, deposition of interlayer dielectric (ILD) 520 and chemical mechanical polishing (CMP) of the ILD 520. The several processing operations can further include dummy gate replacement with high-k metal gate material 530, middle-of-line (MOL) formation to form a frontside contact 540 disposed in contact with the primary S/D epitaxy 510 in the second one 3172 of the S/D regions 317, back-end-of-line (BEOL) formation to form a BEOL layer 550 disposed in contact with the frontside contact 540 and bonding of a carrier wafer 560 to the BEOL layer 550.

The dummy gate structures 315 (see FIG. 3) are thus reconfigured as FET (nFET or pFET) structures 570.

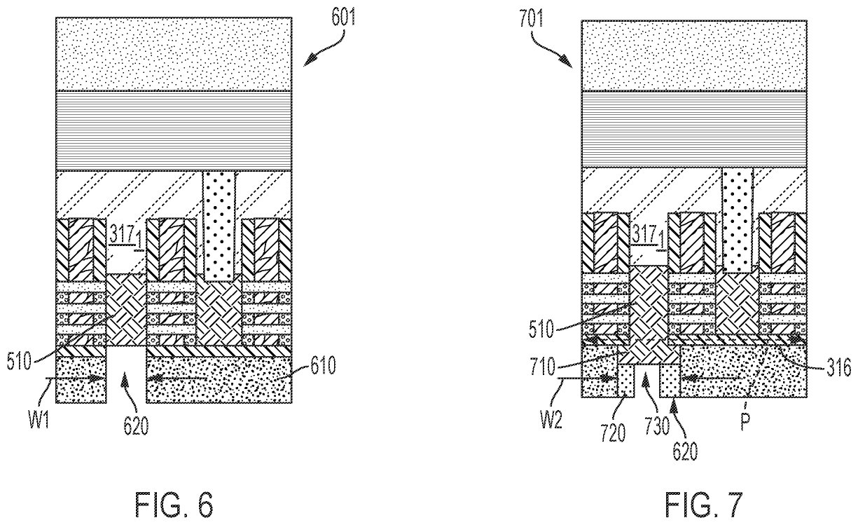

As shown in FIG. 6, a third intermediate structure 601 of a semiconductor device is provided following removal of the substrate 310 (see FIG. 3), deposition of backside ILD 610, CMP of the backside ILD 610 and removal of the sacrificial placeholder 420 (see FIG. 4) applied to the second intermediate structure 501 of FIG. 5. The removal of the sacrificial placeholder 420 leaves an opening 620 in the backside ILD 610, which exposes a lowermost surface of the primary S/D epitaxy 510 in the first one 3171 of the S/D regions 317. The opening 620 has an initial width of W1.

As shown in FIG. 7, a fourth intermediate structure 701 of a semiconductor device is provided following enlargement or widening of the opening 620 to have an enlarged width W2, growth of backside trench S/D epitaxy 710 and deposition of sacrificial spacers 720 applied to the third intermediate structure 601 of FIG. 6. The backside trench S/D epitaxy 710 is disposed in contact with the primary S/D epitaxy 510 in the first one 3171 of the S/D regions 317 and extends from a plane P of the BDI 316 and below the plane P of the BDI 316 and into the opening 620. The deposition of the sacrificial spacers 720 forms the sacrificial spacers 720 in a periphery of the opening 620 such that the sacrificial spacers 720 define an aperture 730 which exposes a central portion of the backside trench S/D epitaxy 710.

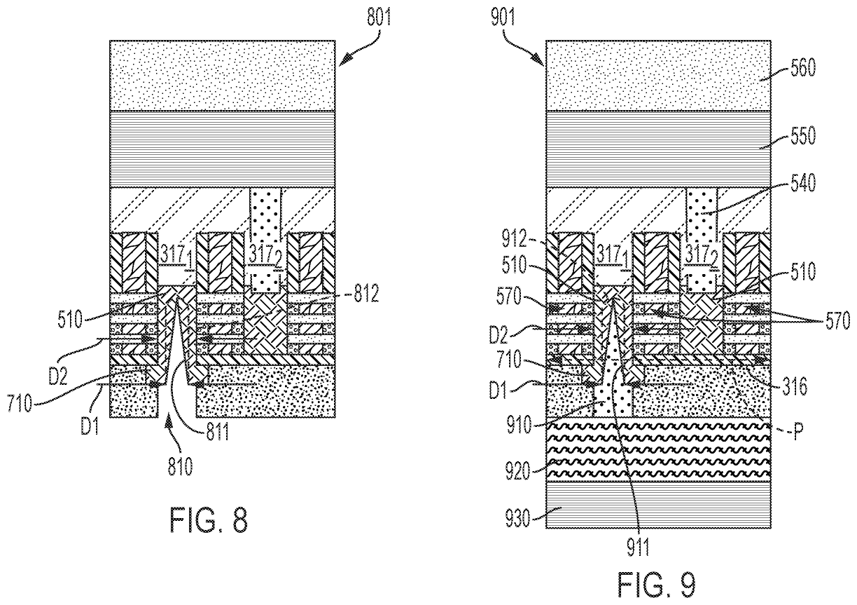

As shown in FIG. 8, a fifth intermediate structure 801 of a semiconductor device is provided following epitaxial gouging into the backside trench S/D epitaxy 710 and the primary S/D epitaxy 510 via the aperture 730 (see FIG. 7) in the first one 3171 of the S/D regions 317 to form a contact opening 810 and removal of the sacrificial spacers 720 (see FIG. 7) applied to the fourth intermediate structure 701 of FIG. 7. The gouging into the backside trench S/D epitaxy 710 and the primary S/D epitaxy 510 in the first one 3171 of the S/D regions 317 can be executed to form the contact opening 810 with a maximum diameter D1 that is smaller than a corresponding diameter D2 of the backside trench S/D epitaxy 710 and the primary S/D epitaxy 510. In addition, the gouging into the backside trench S/D epitaxy 710 and the primary S/D epitaxy 510 can be executed to form the contact opening 810 to have a V-shape 811 or a U-shape 812 or another similar shape.

As shown in FIG. 9, a final structure 901 of a semiconductor device is provided following formation of a backside contact 910 in the first one 3171 of the S/D regions 317 by metallization and formation of a backside power rail 920, which is disposed in contact with the backside contact 910, and a backside power distribution network (BSPDN) 930 applied to the fifth intermediate 801 structure of FIG. 8. The backside power rail 920 is thus communicative with the backside trench S/D epitaxy 710 and the primary S/D epitaxy 510 via the backside contact 910 in the first one 3171 of the S/D regions 317.

The final structure 901 therefore includes the BSPDN 930, the backside power rail 920, the FET structures 570 having S/D regions 317 (i.e., the first one 3171 of the S/D regions 317 and the second one 3172 of the S/D regions 317) between channel regions 318 (see FIG. 3), the primary S/D epitaxy 510 disposed in each of the first one 3171 of the S/D regions 317 and the second one 3172 of the S/D regions 317 and the backside contact 910 as well as the BDI 316 underlying the channel regions 318 and the backside trench S/D epitaxy 710. The backside trench S/D epitaxy 710 is interposed between the primary S/D epitaxy 510 and the backside contact 910 and extends from the plane P of the BDI 316 and below the plane P of the BDI 316. The backside contact 910 is disposed in contact with the backside power rail 920 and the BSPDN 930 at a lower end thereof and in contact with the backside trench S/D epitaxy 710 and the primary S/D epitaxy 510 at an upper end thereof in the first one 3171 of the S/D regions 317. The final structure 901 further includes the carrier wafer 560, the BEOL layer 550 underlying the carrier wafer 560 and the frontside contact 540, which is disposed in contact with the primary S/D epitaxy 510 in the second one 3172 of the S/D regions 317 (see FIG. 3) and the BEOL layer 550.

In greater detail, the backside contact 910 includes a base portion 911 and a gouging portion 912 extending from the base portion 911 and into and through the backside trench S/D epitaxy 712 and into the primary S/D epitaxy 510 in the first one 3171 of the S/D regions 317. The gouging portion 912 has the maximum diameter D1 that is smaller than the corresponding diameter D2 of the backside trench S/D epitaxy 710 and the primary S/D epitaxy 510. In accordance with one or more embodiments of the present invention, the gouging portion 912 of the backside contact 910 gouging into and through the backside trench S/D epitaxy 710 and into the primary S/D epitaxy 510 can have a V-shape 911 or a U-shape 912 or another similar shape.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device, comprising:
a field effect transistor (FET) structure having a source/drain (S/D) region between channel regions;
primary epitaxy disposed in the S/D region; and
a backside contact disposed in contact with and gouging into the primary epitaxy.

2. The semiconductor device according to claim 1, wherein the backside contact has a V-shape gouging into the primary epitaxy.

3. The semiconductor device according to claim 1, wherein the backside contact has a U-shape gouging into the primary epitaxy.

4. The semiconductor device according to claim 1, further comprising bottom dielectric isolation (BDI) underlying the channel regions.

5. The semiconductor device according to claim 4, further comprising backside trench epitaxy disposed in contact with the primary epitaxy and extending below a plane of the BDI.

6. The semiconductor device according to claim 5, wherein the backside contact comprises:
a base portion; and
a gouging portion extending from the base portion and into the backside trench epitaxy and the primary epitaxy.

7. The semiconductor device according to claim 6, wherein the gouging portion has a smaller diameter than the backside trench epitaxy and the primary epitaxy.

8. A semiconductor device, comprising:
a backside power rail;
a field effect transistor (FET) structure having source/drain (S/D) regions between channel regions;
primary epitaxy disposed in each of the S/D regions; and
a backside contact disposed in contact with the backside power rail and the primary epitaxy in a first one of the S/D regions and gouging into the primary epitaxy in the first one of the S/D regions.

9. The semiconductor device according to claim 8, further comprising:
a carrier wafer;
a back-end-of-line (BEOL) layer underlying the carrier wafer; and
a contact disposed in contact with the primary epitaxy in a second one of the S/D regions and the BEOL layer.

10. The semiconductor device according to claim 8, wherein the backside contact has a V-shape gouging into the primary epitaxy.

11. The semiconductor device according to claim 8, wherein the backside contact has a U-shape gouging into the primary epitaxy.

12. The semiconductor device according to claim 8, further comprising bottom dielectric isolation (BDI) underlying the channel regions.

13. The semiconductor device according to claim 12, further comprising backside trench epitaxy disposed in contact with the primary epitaxy and extending below a plane of the BDI.

14. The semiconductor device according to claim 13, wherein the backside contact comprises:
a base portion; and
a gouging portion extending from the base portion and into the backside trench epitaxy and the primary epitaxy.

15. The semiconductor device according to claim 14, wherein the gouging portion has a smaller diameter than the backside trench epitaxy and the primary epitaxy.

16. A semiconductor device fabrication method, comprising:
forming bottom dielectric isolation (BDI) under a gate structure with a source/drain (S/D) region;
replacing a portion of the BDI in the S/D region with a sacrificial placeholder;
growing primary epitaxy over the sacrificial placeholder;
using the sacrificial placeholder to create an opening;
removing the sacrificial placeholder;
enlarging the opening;
growing a backside trench epitaxy in contact with the primary epitaxy and within the opening;
forming sacrificial spacers in a periphery of a remaining portion of the opening to define an aperture;
gouging into the backside trench epitaxy and the primary epitaxy via the aperture to form a contact opening; and
forming a backside contact by metallization of the contact opening.

17. The semiconductor device fabrication method according to claim 16, wherein the enlarging of the opening comprises widening the opening.

18. The semiconductor device fabrication method according to claim 16, wherein the gouging comprises gouging into the backside trench epitaxy and the primary epitaxy via the aperture to form the contact opening with a diameter which is smaller than that of the backside trench epitaxy and the primary epitaxy.

19. The semiconductor device fabrication method according to claim 16, wherein the gouging comprises gouging into the backside trench epitaxy and the primary epitaxy via the aperture to form a V-shaped contact opening.

20. The semiconductor device fabrication method according to claim 16, wherein the gouging comprises gouging into the backside trench epitaxy and the primary epitaxy via the aperture to form a U-shaped contact opening.
